(19) United States
(12) Patent Application Publication
(10) Pub. No.: US 2002/0186764 A1
(43) Pub. Date: Dec. 12, 2002

(54) Method and apparatus for equalizing a radio frequency signal

(75) Inventors: Moeness Gamal Amin, Berwyn, PA (US); Lin He, Rosemont, PA (US); Yimin Zhang, Drexel Hill, PA (US)

Correspondence Address: MOSER, PATTERSON & SHERIDAN, LLP, /SARNOFF CORPORATION, 595 SHREWSBURY AVENUE, SUITE 100, SHREWSBURY, NJ, 07702, US

(73) Assignee: Sarnoff Corporation

(21) Appl. No.: 09/828,324

(22) Filed: Apr. 6, 2001

(51) Int. Cl. H03K 5/159; H03H 7/30; H03H 7/40; H04B 1/10

(52) U.S. Cl. 375/233; 375/350

(57) ABSTRACT

A method and apparatus for equalizing a radio frequency (RF) signal includes a modified constant modulus algorithm (M-CMA) that performs blind equalization on the input channel. The M-CMA uses both amplitude and phase information present in the output signal to minimize a cost function and adjust the tap weights of an equalizer using a gradient recursion equation. Use of both amplitude and phase information results in quicker convergence and faster tracking of dynamic distortions in the input channel in severe multipath environments.

### BACKGROUND OF THE INVENTION

1. Field of the Invention

The invention generally relates to equalizers, and, more particularly, relates to a method and apparatus for performing blind equalization using both amplitude and phase properties of the equalizer output signal.

2. Description of the Related Art

In a radio frequency (RF) transmission channel, a transmitted signal experiences time dispersion due to a deviation in the channel frequency response from the ideal channel characteristics of a constant amplitude and linear phase (constant delay) response. These non-ideal channel characteristics mainly result from multipath distortion, that is, the transmitted signal can take more than one path through the transmission channel. If at least two paths have a time difference comparable with the distance between two symbols transmitted in succession, a symbol on one of these paths will interfere with a following symbol on another, shorter path. This can result in signal fade and intersymbol interference (ISI).

Consequently, to achieve optimal demodulation of an RF signal, an equalizer is required in the receiver system to compensate for the non-ideal channel characteristics by using adaptive filtering. By correcting the amplitude and phase response of the received signal, the equalizer minimizes the ISI of the received signal, thus improving the signal detection accuracy.

Non-ideal channel characteristics are particularly problematic during reception of RF signals in severe multipath environments. Such severe environments introduce additional random dynamics on the amplitude and phase response of the channel. High Doppler frequency, flat and frequency selective fading, and shadowing are the most common dominant factors in signal degradation that decrease receiver performance. Conventional blind equalization techniques fail to quickly converge or form an equalized signal to completely track the dynamic distortions found in such environments.

Therefore, there exists a need in the art for a method and apparatus that exhibits improved equalization in severe multipath environments.

### SUMMARY OF THE INVENTION

The disadvantages associated with the prior art are overcome by a method and apparatus for equalizing a radio frequency (RF) signal using a modified constant modulus algorithm (M-CMA). The M-CMA performs blind equalization by updating the tap weights of an equalizer via a cost function that is derived using both the amplitude and the phase of the output signal. The cost function is minimized using a gradient recursive algorithm and the tap weights are adjusted accordingly. Use of both the amplitude and phase information results in quicker convergence and faster tracking of dynamic distortions in the input channel. The M-CMA operates independently of spacing and modulation scheme of the input signal.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a block diagram of a receiver that uses a modified constant modulus algorithm for blind equalization;

FIG. 2 depicts a detailed block diagram of one embodiment of an equalizer;

FIG. 3A illustrates the mean square error versus symbol sample for the conventional constant modulus algorithm; and

FIG. 3B illustrates the mean square error versus symbol sample for the modified constant modulus algorithm of the present invention.

### DETAILED DESCRIPTION OF THE PREFERRED EMBODIMENT

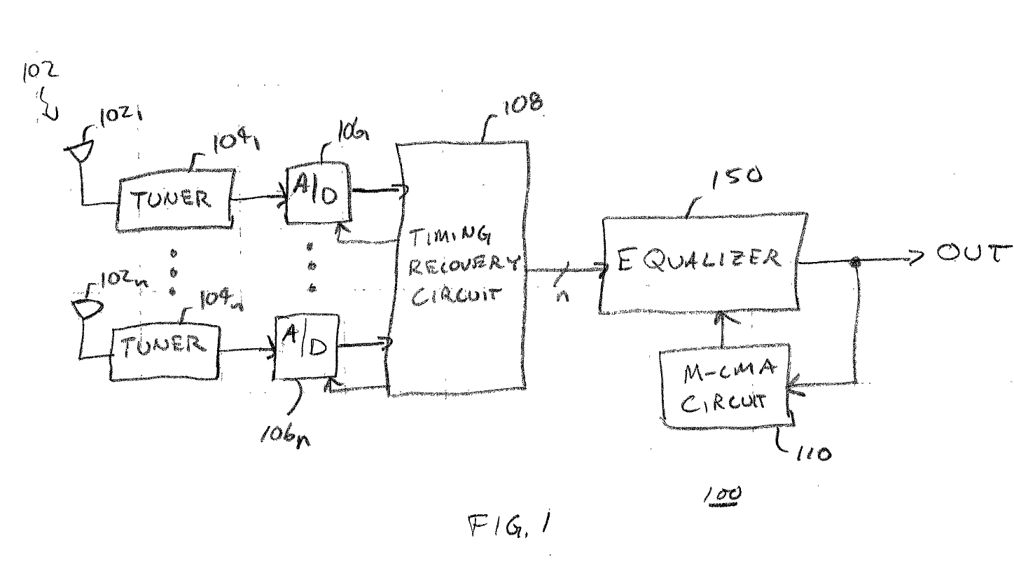

FIG. 1 depicts a block diagram of a receiver 100 that uses a modified constant modulus algorithm (M-CMA) for blind equalization. In the present embodiment of the invention, the receiver 100 is capable of receiving radio frequency (RF) signals in any desired frequency band (e.g., a 5 GHz wireless band). The RF signals can be modulated using any complex modulation scheme, such as, but not limited to, M-ary quadrature amplitude modulation (QAM), or quadrature phase-shift keying (QPSK).

Antennas 102₁ through 102ₙ (collectively antennas 102) receive spatially diverse replicas of a transmitted RF signal. Each antenna 102₁ through 102ₙ is respectively coupled to tuners 104₁ through 104ₙ. The tuners 104 filter and downconvert the received signal to near baseband. The near baseband signals are respectively coupled to the analog-to-digital (A/D) converters 106₁ through 106ₙ. The digitized signals are applied to the joint timing recovery circuit 108. The timing recovery circuit 108 generates a signal at the symbol rate fₛ, synchronizes this signal to the best estimate of the transmitted data, and then identifies symbol timing information for decoding and synchronization purposes.

The samples are then coupled to an equalizer 150. The equalizer 150 comprises a complex equalizer capable of performing blind equalization. The equalized symbols are coupled to an M-CMA circuit 110, which performs an M-CMA algorithm to adjust the tap weights of the equalizer 150. The M-CMA algorithm is independent of spacing, that is, the samples can be symbol spaced or fractionally spaced. The equalized symbols are then available for further processing.

In severe cases, the multipath distortion in the received signal takes on a broad range of characteristics including frequency flat fading, frequency selective fading and Doppler distortion. To combat this set of problems, the equalizer 150 must converge quickly and must be capable of tracking the dynamic distortions present in the channel. The M-CMA algorithm of the present invention results in both quicker convergence and better tracking than conventional constant modulus algorithms (CMAs). The operation of the M-CMA circuit 110 is discussed below.

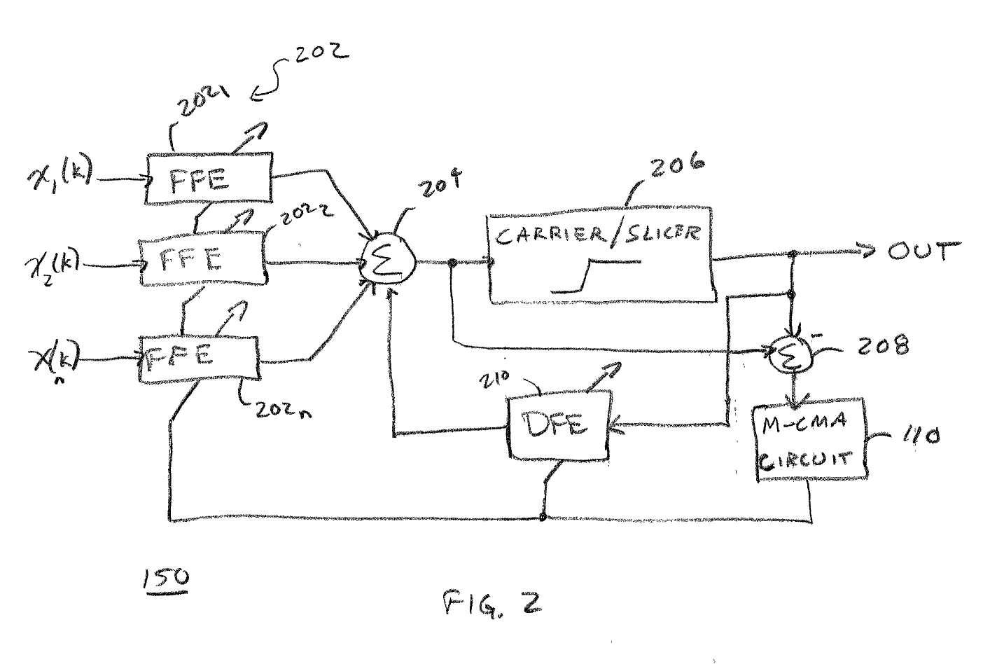

FIG. 2 depicts a detailed block diagram of one embodiment of the equalizer 150 comprising a plurality of feed forward equalizers (FFEs) 202ₙ (n is an integer and the FFEs are collectively referred to by the reference numeral 202), a combiner 204, a carrier loop recovery circuit and slicer combined circuit 206, a subtractor 208, a decision feedback equalizer (DFE) 210, and the M-CMA circuit 110. The FFEs 202 are multi-tap equalizers that delay their respective signals to achieve equal delays in the received signals on a symbol spaced basis. Once spatially and temporally equalized by FFEs 202, the signals are combined in combiner 204. The output of the combiner 204 is coupled to a single circuit 206 comprising both a carrier loop recovery circuit and a slicer.

The carrier/slicer circuit 206 comprises a carrier loop recovery circuit that extracts the carrier from the equalized symbols and a slicer circuit that samples the symbols to generate estimated symbols. The carrier loop recovery circuit is used to correct for any frequency or phase offset in the received signal, thus mitigating some of the Doppler effects. The output of the carrier/slicer circuit 206 is coupled to the DFE 210 for temporal equalization and the removal of intersymbol interference. The output of the DFE 210 is coupled to the combiner 204. The slicer in the carrier/slicer circuit 206 and subtractor 208 are used to produce a symbol error that is coupled to the M-CMA circuit 110, that is, the slicer together with the subtractor 208 compares the estimated symbol sample with the closest known symbol and generates an error signal. As described above, the M-CMA circuit 110 uses the error signal to produce tap weight adjustments for all the equalizers: the FFEs 202₁-202ₙ and the DFE 210.

Although the equalizer 150 has been described as comprising a plurality of FFEs and a DFE, those skilled in the art can readily devise alternative equalizer configurations for use with the present invention.

Referring to both FIGS. 1 and 2, the equalizer 150 performs blind equalization using the output of the M-CMA circuit 110 and, thus, does not require a training sequence embedded in the RF signal to aid in adjusting the tap weights of the equalizers 202 and 210. Conventional CMA algorithms minimize the deviation of the modulus of an equalized signal from a constant by operating on the signal amplitude only. The M-CMA algorithm of the present invention, however, utilizes both amplitude and phase information (i.e., the complex output of the equalizer) to improve equalization performance.

For example, if the received RF signal uses a QAM modulation scheme, the signal can be depicted in signal space by (sₓ, s_{y}), such that

sₓ=(2mₓ−1)d, mₓ=−Lₓ+1, . . . , Lₓ

s_{y}=(2m_{y}−1)d, m_{y}=−L_{y}+1, . . . , L_{y} Eq. 1,

where Lₓ and L_{y} are integer numbers and 2d is the minimal symbol spacing. This representation can be transformed into the following:

$$cos ( \frac{{s}_{x}}{2 d} π ) = 0 \\ cos ( \frac{{s}_{y}}{2 d} π ) = 0. \qquad Eq .2$$

Taking into account the complex equalized signal, the cost function, which represents the cumulative mean square error (MSE), is:

$${J}_{m} ( w ) = E \{ {( {\vert {z}_{k} \vert}^{2} - A )}^{2} + β [ {cos}^{2} ( \frac{{z}_{kr}}{2 d} π ) + {cos}^{2} ( \frac{{z}_{ki}}{2 d} π ) ] \} , \qquad Eq .3$$

where w is the tap weight vector, zₖ is the output of the equalizer after the kth iteration, A is the desired amplitude in the absence of interference, zₖᵣ and zₖᵢ are the real and imaginary parts of zₖ, respectively, and β is a weighting factor that trades off amplitude and phase errors.

The gradient recursion formula for the equalizer tap weights is thus represented by the equation:

wₖ₊₁=wₖ−μₘ∇Jₘ(w)|w=wₖ Eq. 4,

where μₘ is the gradient step size. The derivative of the cost function in equation 3 can be carried out term by term. The derivative of the first term of the cost function, which results from considering the amplitude of the equalizer output, is:

$$\frac{\partial ( E \{ {( {\vert {z}_{k} \vert}^{2} - A )}^{2} \} )}{\partial w} = 4 E \{ ( {\vert {z}_{k} \vert}^{2} - A ) {z}_{k}^{*} {x}_{k} \} , \qquad Eq .5$$

where xₖ is the input signal vector at the kth instant.

The derivative of the second term of the cost function, which results from considering the phase of the equalizer output, can be derived as follows. Expressing zₖᵣ and zₖᵢ explicitly by the tap weight matrix w results in the following relationship:

$$\begin{matrix}{z}_{kr} = \frac{{z}_{k} + {z}_{k}^{*}}{2} = \frac{{w}^{H} {x}_{k} + {x}_{k}^{H} w}{2} \\ {z}_{ki} = \frac{{z}_{k} - {z}_{k}^{*}}{2 j} = \frac{{w}^{H} {x}_{k} - {x}_{k}^{H} w}{2 j} .\end{matrix} \qquad Eq .6$$

From equation 6, it follows that the derivatives of zₖᵣ and zₖᵢ are:

$$\frac{\partial {z}_{kr}}{\partial w} = {x}_{k} \\ \frac{\partial {z}_{ki}}{\partial w} = - j {x}_{k} . \qquad Eq .7$$

Thus, the derivative of the second term of the cost function is:

$$\begin{matrix}\frac{\partial ( E \{ {cos}^{2} ( \frac{{z}_{kr}}{2 d} π ) + {cos}^{2} ( \frac{{z}_{ki}}{2 d} π ) \} )}{\partial w} = - E \{ η {x}_{k} \} , \\ where & Eq .8 \\ η = \frac{π}{2 d} [ sin ( \frac{{z}_{kr}}{d} π ) - j sin ( \frac{{z}_{ki}}{d} π ) ] . & Eq .9\end{matrix}$$

Combining the results of equations 3, 5, and 8, the derivative of the cost function for the M-CMA algorithm is:

$$∇ {J}_{m} ( w ) = E \{ [ 4 ( {\vert {z}_{k} \vert}^{2} - A ) {z}_{k}^{*} - β \frac{π}{2 d} [ sin ( \frac{{z}_{kr}}{d} π ) - j sin ( \frac{{z}_{ki}}{d} π ) ] ] {x}_{k} \} . \qquad Eq .10$$

Therefore, the gradient recursion formula used by the M-CMA algorithm of the present invention to adjust the tap weights of the equalizer 150 is:

wₖ₊₁=wₖ−μₘφxₖ Eq. 11,

where

$$ϕ = ( {\vert {z}_{k} \vert}^{2} - A ) {z}_{k}^{*} - α \frac{1}{d} [ sin ( \frac{{z}_{kr}}{d} π ) - j sin ( \frac{{z}_{ki}}{d} π ) ] . \qquad Eq .12$$

Although the above derivation of the gradient recursion formula for the M-CMA algorithm was described in using QAM modulation, those skilled in the art understand that the present invention can be used on signals having any complex modulation scheme.

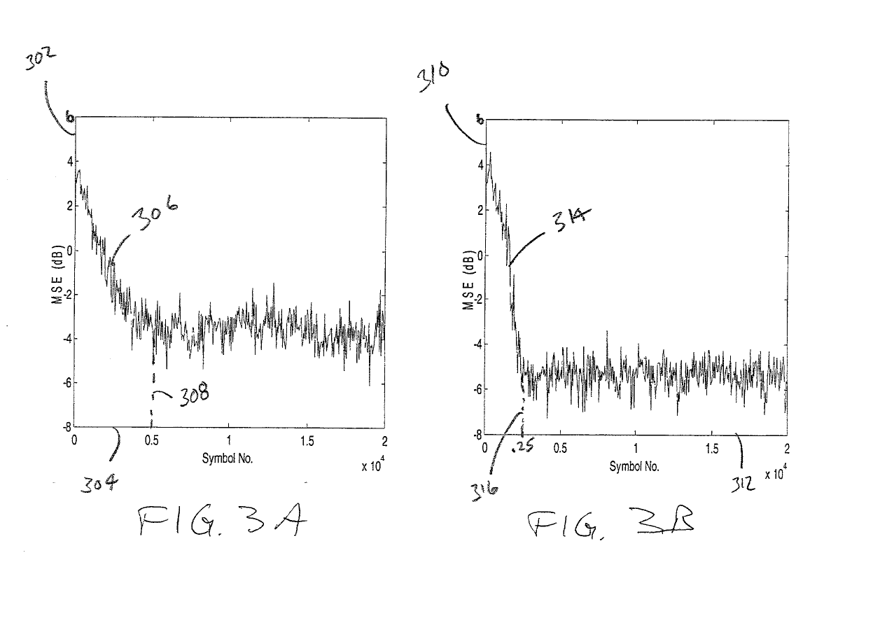

The M-CMA algorithm exhibits improved performance when compared with results obtained using convention CMA algorithms. This is graphically illustrated in FIG. 3. FIG. 3A shows the MSE versus symbol samples after equalization using the conventional CMA algorithm. FIG. 3B shows the MSE versus symbol samples after equalization using the M-CMA algorithm. Referring in FIG. 3A, axis 302 represents the MSE in decibels, axis 304 represents the symbol number is tens of thousands, and plot 306 represents the convergence of a conventional CMA algorithm. As shown, the conventional CMA algorithm converges after approximately 5000 symbols (shown by reference numeral 308).

Referring now to FIG. 3B, axis 310 represents the MSE in decibels, axis 312 represents the symbol number in tens of thousands, and plot 314 represents the convergence of the M-CMA algorithm of the present invention. As shown, the M-CMA algorithm converges after approximately 2500 symbols (shown by reference numeral 316). The faster response time of the M-CMA algorithm improves the tracking of dynamic signal distortions, including flat and frequency selective fading, and shadowing.

As discussed above, the M-CMA algorithm can be contained in a M-CMA circuit 110, which is coupled to the equalizer 150. Alternatively, the M-CMA algorithm, the equalizer 150, or both can be represented by software. Moreover, such a software application can be loaded from a storage device, e.g., a magnetic or optical disk, and can reside in the memory of the computer. As such, the M-CMA algorithm of the present invention can be stored on a computer readable medium.

While foregoing is directed to the preferred embodiment of the present invention, other and further embodiments of the invention may be devised without departing from the basic scope thereof, and the scope thereof is determined by the claims that follow.

1. A method of equalizing a radio frequency (RF) signal comprising:
generating a cost function using amplitude and phase components of the output signal of an equalizer;
minimizing said cost function using a gradient recursion algorithm; and
adjusting the tap weights of said equalizer using the result of said gradient recursion algorithm.

2. The method of claim 1 wherein said cost function is defined by the equation
$${J}_{m} ( w ) = E \{ {( {\vert {z}_{k} \vert}^{2} - A )}^{2} + β [ {cos}^{2} ( \frac{{z}_{kr}}{2 d} π ) + {cos}^{2} ( \frac{{z}_{ki}}{2 d} π ) ] \} ,$$
where: w is a tap weight vector, zₖ is the output of the equalizer after the kth iteration, A is the desired amplitude in the absence of interference, zₖᵣ and zₖᵢ are the real and imaginary parts of zₖ, respectively, and β is a weighting factor.

3. The method of claim 1 wherein said gradient recursion algorithm is defined by the equation wₖ₊₁=wₖ−μₘ∇Jₘ(w)|w=wₖ, where: wₖ₊₁ is a tap weight vector at the kth+1 instant, wₖ is said tap weight vector at the kth instant, μₘ is the gradient step size, and ∇Jₘ(w) is the gradient of said cost function.

4. A apparatus for receiving a radio frequency (RF) signal comprising:
at least one antenna for receiving the RF signal;
at least one tuner for selecting the RF signal from a desired frequency band;
an equalizer having a plurality of tap weights; and
a modified constant modulus algorithm (M-CMA) circuit for adjusting said plurality of tap weights.

5. The apparatus of claim 4 wherein said equalizer comprises:
a plurality feed forward equalizers (FFEs), where each FFE is coupled to an antenna;
a combiner for combining the output signals from each of said plurality of feed forward equalizers to form a combined signal;
a carrier/slicer circuit for extracting the carrier from the combined signal and generating a symbol error signal; and
a decision feedback equalizer for suppressing inter-symbol interference in said combined signal;
wherein said M-CMA circuit adjusts the tap weights of said plurality of feed forward equalizers and said decision feedback equalizer.

6. The apparatus of claim 4 wherein said M-CMA circuit adjusts said tap weights by minimizing a cost function using a gradient recursion algorithm, wherein said cost function is derived using the amplitude and the phase of the output signal of said equalizer.

7. The apparatus of claim 6 wherein said cost function is defined by the equation
$${J}_{m} ( w ) = E \{ {( {\vert {z}_{k} \vert}^{2} - A )}^{2} + β [ {cos}^{2} ( \frac{{z}_{kr}}{2 d} π ) + {cos}^{2} ( \frac{{z}_{ki}}{2 d} π ) ] \}$$
where: w is a tap weight vector, zₖ is the output of the equalizer after the kth iteration, A is the desired amplitude in the absence of interference, zₖᵣ and zₖᵢ are the real and imaginary parts of zₖ, respectively, and β is a weighting factor.

8. The apparatus of claim 6 wherein said gradient recursion algorithm is defined by the equation wₖ₊₁=wₖ−μₘ∇Jₘ(w)|w=wₖ, where: wₖ₊₁ is a tap weight vector at the kth+1 instant, wₖ is said tap weight vector at the kth instant, μₘ is the gradient step size, and ∇Jₘ(w) is the gradient of said cost function.

9. An apparatus for equalizing a radio frequency (RF) signal comprising:
a plurality of feed forward equalizers;
a combiner for combining the output signals from each of said plurality of feed forward equalizers to form a combined signal;
a decision feedback equalizer for suppressing inter-symbol interference in said combined signal; and
a modified constant modulus algorithm (M-CMA) circuit for adjusting the tap weights of said plurality of feed forward equalizers and said decision feedback equalizer.

10. The apparatus of claim 9 wherein said M-CMA circuit adjusts said tap weights by minimizing a cost function using a gradient recursion algorithm, wherein said cost function is derived using the amplitude and the phase of the equalized output signal.

11. The apparatus of claim 10 wherein said cost function is defined by the equation
$${J}_{m} ( w ) = E \{ {( \vert {z}_{k} {\vert}^{2} - A )}^{2} + β [ {cos}^{2} ( \frac{{z}_{k r}}{2 d} π ) + {cos}^{2} ( \frac{{z}_{k i}}{2 d} π ) ] \} ,$$
where: w is a tap weight vector, zₖ is the output of the equalizer after the kth iteration, A is the desired amplitude in the absence of interference, zₖᵣ and zₖᵢ are the real and imaginary parts of zₖ, respectively, and μ is a weighting factor.

12. The apparatus of claim 10 wherein said gradient recursion algorithm is defined by the equation wₖ₊₁=wₖ−μₘ∇Jₘ(w)|w=wₖ, where: wₖ₊₁ is a tap weight vector at the kth+1 instant, wₖ is said tap weight vector at the kth instant, μₘ is the gradient step size, and ∇Jₘ(w) is the gradient of said cost function.
